(19) United States
(12) Patent Application Publication
(10) Pub. No.: US 2007/0025566 A1
(43) Pub. Date: Feb. 1, 2007

(54) System and method for processing audio data

(76) Inventor: Robert W. Reams, Everett, WA (US)

Correspondence Address: Mr. Christopher John Rourk;Jackson Walker LLP, 901 Main Street, Suite 6000, DALLAS, TX, 75202, US

(21) Appl. No.: 11/433,285

(22) Filed: May 12, 2006

Related U.S. Application Data
(63) Continuation of application No. 10/380,190, filed on Mar. 7, 2003.
(60) Provisional application No. 60/231,409, filed on Sep. 8, 2000.
(60) Provisional application No. 60/231,081, filed on Sep. 8, 2000.
(60) Provisional application No. 60/231,076, filed on Sep. 8, 2000.
(60) Provisional application No. 60/231,408, filed on Sep. 8, 2000.
(60) Provisional application No. 60/231,450, filed on Sep. 8, 2000.

(51) Int. Cl. H03G 5/00

(52) U.S. Cl. 381/98

(57) ABSTRACT

A system for processing audio data is provided. The system includes a spectral shaping system that receives sample audio data and generates spectral characteristic data for a plurality of spectral bands. The spectral characteristic data includes spectral characteristic data for predetermined frequency bands for a combination of one or more left channel data, one or more right channel data, or one or more additional channel data such as those defined pursuant to MPEG-2, and a difference between the one or more left channel data, the one or more right channel data, or the one or more additional channel data. An audio processing system receives the spectral characteristic data and processes the audio data so as to provide the spectral characteristic data for the spectral bands of the audio data.

### RELATED APPLICATIONS

This application claims priority to U.S. Provisional patent applications No. 60/231,450, entitled “Adaptive Spectral Shaping;” No. 60/231,409, entitled “Adaptive Energy Windowing;” No. 60/231,076, entitled “Adaptive Image Width Management;” No. 60/231,408 entitled “High Definition Process for Lossy Compression of Digitally Encoded Audio;” and No. 60/231,081, entitled “Audio Signal Enhancement,” each of which were filed on Sept. 8, 2000, and which are hereby incorporated by reference for all purposes, and to pending utility application Ser. No. 10/380,190, filed Mar. 7, 2003, which is hereby incorporated by reference for all purposes.

### FIELD OF THE INVENTION

The present invention relates generally to the processing of audio data, and more specifically to control of spectral characteristics and audio image characteristics of the audio data to prevent unintentional masking of perceptual queues.

### BACKGROUND OF THE INVENTION

Systems and methods for processing audio data are known in the art. Such systems and methods allow a producer or other audio data processing personnel to control characteristics of the audio data, to provide the audio data with aesthetically pleasing characteristics. For example, one common form of audio data processing in this regard is equalization. Equalization breaks the audio data signal into a set of frequency bands, and allows the relative levels of the frequency bands to be controlled. In this manner, it is possible for the audio data to be modified so as to decrease the prominence of certain spectral components, such as high frequency components, and to increase the prominence of other special components, such as low frequency components. Other types of audio data processing include controlling the balance of a stereophonic signal and controlling the phase of the stereophonic signal.

Audio data processing thus focuses on several concepts: spectral shaping and audio image. Spectral shaping refers to the settings of equalization bands, whereas audio image refers to the three-dimensional characteristic of stereophonic audio data as heard by a listener. For example, a listener in a room with two loudspeakers, one emitting stereophonic left channel signals and the other emitting stereophonic right channel signals, may seem to hear sound coming from the side of the room, the back of the room, or locations other than the two loudspeakers. The ability to present three-dimensional aesthetic qualities to music is referred to as the audio image of the audio data. Audio data production personnel are recognized for their abilities to control and process audio data so as to produce characteristic aesthetic qualities, and this ability is generally considered to be artistic as opposed to analytical.

One reason why some processed audio data is more aesthetically appealing than other processed audio data can be attributed to the effect of the audio data on the human hearing mechanism. The human hearing mechanism includes the eardrum (which receives audio data from the environment), the middle ear (which includes the anvil, stirrup, and hammer bones and associated muscles, and which transfer the sound energy from the ear drum to the inner ear), and the inner ear (which includes the organ of Corti, which converts the sound energy to nerve impulses). The sound of interest to the brain is characterized by perceptual queues, such as those marking the beat, those that are recognized as voices, and other similar perceptual queues. Perceptual queues are masked when the brain focuses on certain spectra and controls the organ of Corti to cause it to ignore spectra that fall below a dominance threshold. When the human brain is processing audio data in this manner, it causes fatigue and expenditure of energy in the listener that can also contribute to masking of data.

### SUMMARY OF THE INVENTION

In accordance with the present invention, a system and method for processing audio data are provided which overcome known problems with inspecting of components. In particular, a system and method for processing audio data are disclosed that allow spectral characteristics and audio image characteristics of audio data to be controlled, to prevent masking of perceptual queues.

In accordance with an exemplary embodiment of the present invention, a system for processing audio data is provided. The system includes a spectral shaping system that receives sample audio data and generates spectral characteristic data for a plurality of spectral bands. The spectral characteristic data includes spectral characteristic data for predetermined frequency bands for a combination of one or more left channel data, one or more right channel data, or one or more additional channels such as those defined pursuant to MPEG-2, and a difference between the one or more left channel data, the one or more right channel data, or the one or more additional channel data. An audio processing system receives the spectral characteristic data and processes the audio data so as to provide the spectral characteristic data for the spectral bands of the audio data.

Embodiments of the present invention provide many important technical advantages. One advantage of an embodiment of the present invention is a system and method for processing audio data that allows the spectral characteristics and the audio image characteristics of an audio data sample to be quantified and duplicated in target audio data. Another advantage of the present invention is a system and method for processing audio data that reduces the amount of data without affecting the aesthetic qualities of the data by eliminating data that would normally mask perceptual queues to human hearing. Yet another advantage of the present invention is a system and method for processing audio data that reduces unintentional masking of perceptual queues.

Those skilled in the art will further appreciate the advantages and superior features of the invention together with other important aspects thereof on reading the detailed description that follows in conjunction with the drawings.

### BRIEF DESCRIPTION OF THE DRAWINGS

FIG. 1 is a diagram of system for processing audio data by controlling masking of perceptual queues in accordance with an exemplary embodiment of the present invention;

FIG. 2 is a diagram of a system for selecting sample audio data in accordance with an exemplary embodiment of the present invention;

FIG. 3 is a diagram of a system for providing spectral shaping functionality in accordance with an exemplary embodiment of the present invention;

FIG. 4 is a diagram of a system for providing audio image management functionality in accordance with an exemplary embodiment of the present invention;

FIG. 5 is a diagram of a system for processing audio data in accordance with an exemplary embodiment of the present invention;

FIG. 6 is a diagram of a system for managing audio data in accordance with an exemplary embodiment of the present invention;

FIG. 7 is a flowchart of a method for processing audio data in accordance with an exemplary embodiment of the present invention;

FIG. 8 is a flow chart of a method for generating spectral characteristics in accordance with an exemplary embodiment of the present invention;

FIG. 9 is a flow chart of a method for determining audio image characteristics in accordance with an exemplary embodiment of the present invention;

FIG. 10 is a flow chart of a method for processing audio data using spectral characteristics and audio image characteristics in accordance with an exemplary embodiment of the present invention;

FIG. 11 is a flow diagram of a process for modifying audio data using spectral characteristics and audio image characteristics in accordance with an exemplary embodiment of the present invention;

FIG. 12 is a diagram of a convolve control for generating causal or acausal audio data in accordance with an exemplary embodiment of the present invention;

FIG. 13 is a diagram of a spectral partition control for processing audio data in accordance with an exemplary embodiment of the present invention; and

FIG. 14 is a diagram of an adaptive gain control for processing audio data in accordance with an exemplary embodiment of the present invention.

### DETAILED DESCRIPTION OF PREFERRED EMBODIMENTS

In the description that follows, like parts are marked throughout the specification and drawings with the same reference numerals, respectively. The drawing figures might not be to scale, and certain components can be shown in generalized or schematic form and identified by commercial designations in the interest of clarity and conciseness.

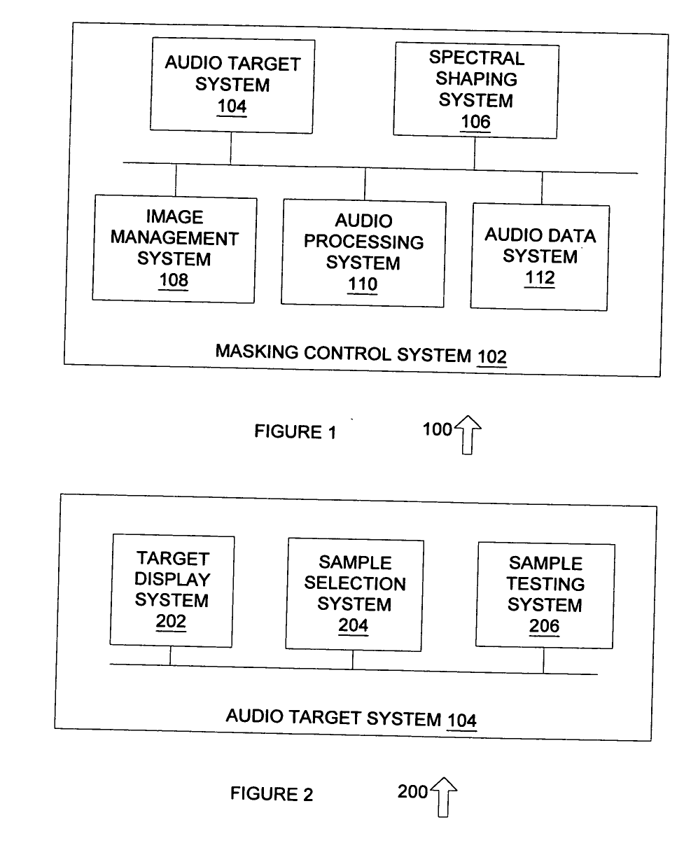

FIG. 1 is a diagram of system 100 for processing audio data by controlling masking of perceptual queues in accordance with an exemplary embodiment of the present invention. System 100 allows audio data to be processed in a. manner that reduces the number of unintentional masking events, and which allows previously produced audio data which has been aesthetically determined to have optimal control of masking events to be used as a template for processing other audio data.

System 100 includes masking control system 102 and audio target system 104, spectral shaping system 106, image management system 108, audio processing system 110, and audio data system 112, each of which can be implemented in hardware, software or a suitable combination of hardware and software, which can be one or more software systems operating on a general purpose processing platform. As used herein, a software system can include user readable code, source code, machine readable code, object code, one or more objects, agents, threads, line of code, subroutines, separate software applications, two or more lines of code or other suitable software structures operating in two or more separate software applications, on two or more different processors, or other suitable software architectures. In one exemplary embodiment, a software system can include one or more lines of code or other suitable software structures operating in a general purpose software application, such as an operating system, and one or more lines of code or other suitable software structures operating in a specific purpose software application.

Masking control system 102 allows masking of perceptual cues to be controlled, so as to optimize the aesthetic qualities and intelligibility of audio data. In one exemplary embodiment, masking control system 102 maintains predetermined spectral characteristics, predetermined audio image characteristics, or other suitable characteristics or combinations of characteristics for audio data. Likewise, masking control system 102 can be used to process an audio sample that has been determined to have desired aesthetic qualities so as to isolate the spectral characteristics, the audio image characteristics, or other desirable characteristics and to allow those characteristics to be used in other audio data or for the processing of other audio data.

Audio target system 104 allows previously recorded audio data to be presented in a manner that allows a user to identify portions of the previously recorded audio data having desirable aesthetic qualities. For example, a musician or producer of audio data may desire to process target audio data in a manner so as to make it “sound like” other audio data that has been previously recorded and processed. Audio target system 104 allows the user to listen to the previously recorded audio data, observe one or more characteristics of the audio data, and mark sections of the audio data that can be used to generate samples. This sample audio data is then processed by other systems of masking control system 102 to generate spectral characteristic data, audio image characteristic data, and other audio characteristic data that can be used to process target audio data, so as to provide the target audio data with similar aesthetic characteristics as the sample audio data. Audio target system 104 can also allow a user to modify the audio characteristic data, such as spectral characteristic data, audio image characteristic data, or other suitable characteristic data, so as to determine whether such changes improve the aesthetic qualities, decrease masking of perceptual queues, or have other desirable effects.

Spectral shaping system 106 processes audio data and generates spectral characteristic data, such as to determine the spectral characteristics of sample audio data that has acceptable aesthetic qualities, to determine the spectral characteristics of target audio data and to modify those spectral characteristics so as to improve the aesthetic quality and decrease inadvertent or unintentional masking, or for other suitable purposes. In one exemplary embodiment, spectral shaping system 106 can include user modifiable band widths for the right stereophonic channel, theleft stereophonic channel, multiple additional channels such as those defined pursuant to MPEG-2 or other suitable standards, including a subwoofer channel, or the sum(s) and/or difference(s) of these channels that allow the user to break audio data into two or more frequency bands for subsequent audio data processing. Spectral shaping system 106 can then process sample audio data to identify the signal magnitude within each spectral band, and to detect characteristics of how the signal magnitude changes over time and in regards to other characteristics, such as the rate of change of the signal magnitude of the spectral band, other spectral band component magnitudes and rates of change, and other suitable data. In this manner, spectral shaping system 106 allows a user to determine the spectral characteristic data of sample audio data, modify the spectral characteristic data, and to save the spectral characteristic data for use in processing target audio data.

Image management system 108 processes audio data and generates audio image characteristic data, such as to determine the audio image characteristics of sample audio data that has acceptable aesthetic qualities, to determine the audio image characteristics of target audio data and to modify those audio image characteristics so as to improve the aesthetic quality and decrease inadvertent or unintentional masking, or for other suitable purposes. In one exemplary embodiment, image management system 108 can isolate one or more audio image components for processing, such as causal audio image data (such as by adding right and left stereophonic channel data, multiple additional channels such as those defined pursuant to MPEG-2, including a subwoofer channel), acausal audio image data (such as the differences between the right stereophonic channel, the left stereophonic channel data, or any of multiple additional channels such as those defined pursuant to MPEG-2, including a subwoofer channel), and other suitable audio image components. Image management system 108 can further include user modifiable bandwidths that allow the user to separate the causal and acausal audio data into two or more frequency bands for subsequent audio data processing. Image management system 108 can then process sample audio data to identify the signal magnitude within each spectral band, and to detect characteristics of how the signal magnitude changes over time and in regards to other characteristics, such as the rate of change of the signal magnitude of the spectral band, other spectral band component magnitudes and rates of change, and other suitable data. In this manner, image management system 108 allows a user to determine the audio image characteristic data of sample audio data, modify the audio image characteristic data, and to save the audio image characteristic data for use in processing target audio data.

Audio processing system 110 is coupled to spectral shaping system 106 and image management system 108, and receives spectral characteristic data and audio image characteristic data for use in processing audio data. As used herein, the term “couple,” and its cognate terms such as “couples” and “coupled”, can include a physical connection (such as through a copper conductor), a virtual connection (such as one or more randomly assigned memory locations of a data memory device), a logical connection (such as through one or more logical devices of a semiconducting circuit), a wireless connection, other suitable connections, or a suitable combination of such connections. In one exemplary embodiment, systems and components are coupled to other systems and components through intervening systems and components, such as through an operating system of a digital signal processor.

Audio processing system 110 can receive spectral characteristic data from spectral shaping system 106, and can apply the spectral characteristic data to target audio data so as to impart the target audio data with user-controllable aesthetic characteristics, such as those obtained from sample audio data, user-modified or generated spectral characteristic data, or other suitable spectral characteristic data. Likewise, audio processing system 110 allows the user to modify or control the spectral characteristic data so as to determine the effect of the modifications on the aesthetic qualities of the audio data. Audio processing system 110 can also receive audio image characteristic data from image management system 108, and can apply the audio image characteristic data to target audio data, can allow a user to modify the audio image characteristic data so as to determine the effect on the aesthetic qualities of the audio data, and can perform other suitable functions.

Audio data system 112 performs processing and compression of target audio data after spectral characteristic data and audio image characteristic data processing has been performed. In one exemplary embodiment, audio data system 112 allows one or more versions of unprocessed target audio data and processed target audio data to be managed, so as to allow a user to compare various processing formats to determine which provides the desired aesthetic qualities. Audio data system 112 also performs compression of the audio data, such as to reduce the amount of data without effecting the aesthetic qualities of the audio data, such as by inadvertent masking.

In operation, system 100 allows audio data to be processed to improve the aesthetic quality of the audio data and to decrease inadvertent or unintentional masking. System 100 allows sample audio data to be analyzed to determine its spectral characteristics and audio image characteristics, and can process target audio data using the spectral characteristic data and audio image characteristic data to make it “sound like” the sample audio data. In this regard, when the target audio data “sounds like” the sample audio data, it has aesthetic qualities such as those related to the human hearing mechanism that prevent unintentional masking of preferred perceptual queues in audio data.

FIG. 2 is a diagram of a system 200 for selecting sample audio data in accordance with an exemplary embodiment of the present invention. System 200 includes audio target system 104 and target display system 202, sample selection system 204, and sample testing system 206, each of which can be implemented in hardware, software, or a suitable combination of hardware and software, and which can be one or more software systems operating on a general purpose processing platform.

Target display system 202 allows sample audio data to be displayed in a manner that allows the user to select predetermined portions of the sample audio data. In one exemplary embodiment, target display system 202 provides a graphic display of the audio signal data as it changes over time, to allow the user to observe one or more characteristics of the sample audio data. For example, target display system 202 can display spectral characteristics of the sample audio data, audio image characteristics of the sample audio data, or other suitable characteristics of the sample audio data. In another exemplary embodiment, target display system 202 interfaces with spectral shaping system 106 and image management system 108 to perform the analysis of the sample audio data. Likewise, target display system 202 can include independent functionality for generating spectral characteristics and audio image characteristics.

Sample selection system 204 allows the user to mark and select portions of the sample audio data having suitable aesthetic characteristics. In one exemplary embodiment, spectral shaping system 106, image management system 108, and other suitable systems can include artificial intelligence systems, such as one or more neural networks or other suitable artificial intelligence systems, that can be trained using the sample audio data so as to provide improved processing control of the target audio data without operator intervention. In this exemplary embodiment, sample selection system 204 tracks the number of data points required (which corresponds to the time length of the sample audio data), and allows the user to determine whether the audio sample has sufficient length to allow such artificial intelligence systems to be trained.

For example, if a 10-second sample is required in order to train certain artificial intelligence components, then sample selection system 204 can allow the user to listen to the sample audio data to determine whether the aesthetic characteristics are desirable while viewing a graphical display that indicates whether the sample has sufficient length. In this manner, if there are only certain portions of the audio sample that have the aesthetic characteristics desired by the user, sample selection system 204 allows the user to mark those portions to determine which portions have an acceptable length, to assign a relative ranking to each portion, or to perform other suitable processes.

Sample testing system 206 allows a user to test different sets of spectral characteristic data, audio image characteristic data, and other suitable characteristic data with target audio data, such as to determine which set of spectral and/or audio image characteristic data provides the desired aesthetic qualities. In one exemplary embodiment, sample testing system 206 allows the user to compare two or more different tracks of processed target audio data to determine the track having preferred aesthetic characteristics, such as by allowing the user to label characteristic sets, to process the target audio data with each characteristic set, and to save each track of processed target audio data for comparison. In this manner, the user can compare two or more tracks in any desired order to determine the characteristic set having the aesthetic qualities sought by the user.

In operation, system 200 allows sample audio data to be processed to allow the spectral characteristics, audio image characteristics, and other suitable characteristics of the sample audio data to be monitored, extracted, and stored for use in processing target audio data. System 200 allows the user to select portions of sample audio data having preferred spectral characteristics, audio image characteristics, and other characteristics so that these characteristics can be quantified and used for processing of target audio data without operator intervention or control. Likewise, system 200 allows users to modify the spectral characteristic data, audio image characteristic data, or other suitable data, save the characteristic data as one or more sets, and apply the sets of characteristic data to target audio data to determine the effect on the aesthetic qualities of the target audio data.

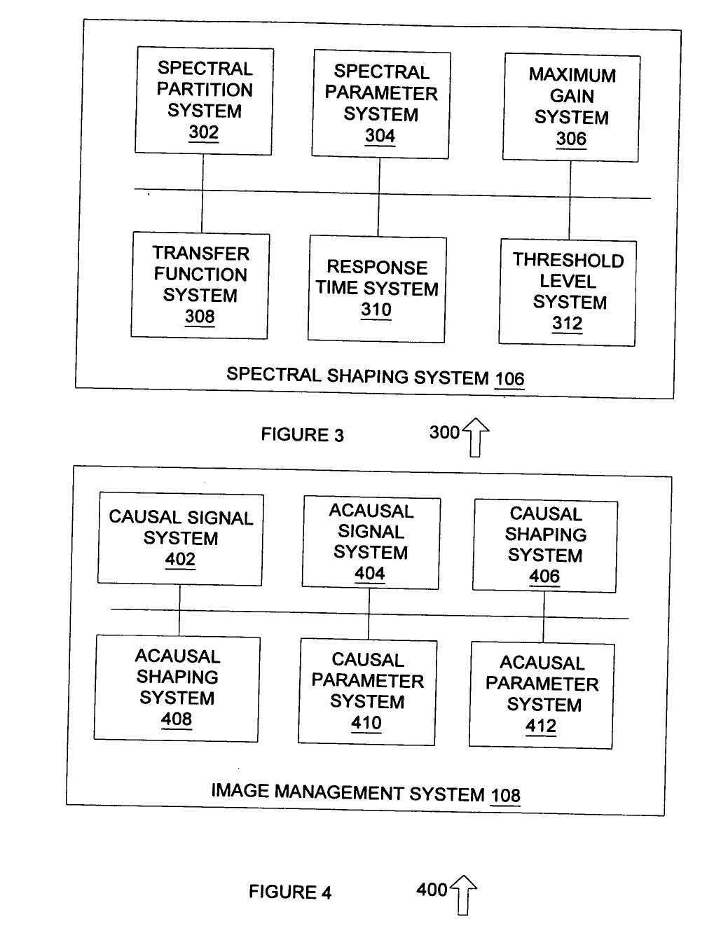

FIG. 3 is a diagram of a system 300 for providing spectral shaping functionality in accordance with an exemplary embodiment of the present invention. System 300 includes spectral shaping system 106 and spectral partition system 302, spectral parameter system 304, maximum gain system 306, transfer function system 308, response time system 310, and threshold level system 312, each of which can be implemented in hardware, software, or a suitable combination of hardware and software, and which can be one or more software systems operating on a general purpose processing platform.

Spectral partition system 302 allows the frequency spectrum of an audio data signal to be separated into user selectable bands. In one exemplary embodiment, spectral partition system 302 can have a number of bands equivalent to a number of artificial intelligence systems that are used to analyze each band to determine the spectral characteristics, such as six. Spectral partition system 302 can further allow the user to select any suitable band width for each band, such as 0 to 50 Hz, 50 to 200 Hz, 200 to 800 Hz, 800 to 3200 Hz, 3200 to 12800 Hz, and 12800 to 22000 Hz, or other suitable combinations of bandwidths. In this manner, spectral partition system 302 allows the user to optimize the number of bands in the frequency ranges that human hearing is most sensitive to. Spectral partition system 302 also allows a user to select and mark two or more preset spectral partitions, such as to allow the user to compare spectral partition settings. Spectral partition system 302 can also assign frequency bandwidths based upon the relative audio data content of frequency bandwidths. For example, if an initial bandwidth assignment of 0 to 50 Hz, 50 to 200 Hz, 200 to 800 Hz, 800 to 3200 Hz, 3200 to 12800 Hz, and 12800 to 22000 Hz is used, and no audio data is present below 800 Hz or above 4000 Hz for a section of audio data that lasts greater than a predetermined length of time, then spectral partition system 302 can re-allocate the bands to the 800 to 4000 Hz frequency range, can generate an alert for an operator and request operator-assisted reallocation, can select bandwidth reallocation based on predetermined selections from a library of characteristic sets, and can perform other suitable functions.

Spectral parameter system 304 processes audio data so as to determine the spectral characteristics of the audio data. In one exemplary embodiment, spectral parameter system. 304 can include an artificial intelligence system such as one or more neural networks, each having a suitable number of inputs, modifiers, conditionals, or other suitable characteristics and one or more outputs, and a transfer function that relates the inputs, modifiers, conditionals, or other suitable characteristics to the output. In one exemplary embodiment, a parametric filter can be used having bandwidth, frequency, gain, threshold, response time, or other suitable characteristics as inputs, modifiers, conditionals, or other suitable characteristics. Likewise, an open variable transfer function such as a second order polynomial, a first order butterworth filter, or other suitable transfer functions can be used. In this manner, spectral parameter system 304 can determine spectral characteristics from sample audio data, such as by training a neural network, which can then be applied to target audio data. Likewise, spectral parameter system 304 can allow a user to modify the inputs, modifiers, conditionals, or other suitable characteristics so as to determine the effect on the aesthetic qualities of audio data processed using the spectral characteristics generated by spectral parameter system 304.

Maximum gain system 306 allows a user to select the maximum gain setting for a spectral characteristic, such as a gain level. In this manner, excessive gain can be controlled so as to prevent masking of perceptual queues within a spectral band. Maximum gain system 306 can also be used to detect the maximum gain of sample audio data. Maximum gain system 306 allows maximum gain to be set for each spectral band, a set of spectral bands, every spectral band, or other suitable combinations.

Transfer function system 308 allows a user to assign a transfer function for use by a spectral parameter system 304. In one exemplary embodiment, transfer function system 308 allows a user to select a filter type, such as a butterworth filter, a Bessel filter, or other suitable types of transfer functions for controlling the characteristics of the spectral band and the relationship of the spectral band to other characteristics of the audio data. Transfer function system 308 thus allows a user to compare target audio data that has been processed using different transfer functions to determine the transfer function providing optimal aesthetic qualities. Transfer function system 308 can also be used to detect the transfer function of sample audio data. Transfer function system 308 allows the transfer function to be set for each spectral band, a set of spectral bands, every spectral band, or other suitable combinations.

Response time system 310 allows a user to select a response time over which changes in spectral characteristics should be controlled. In one exemplary embodiment, the response of human hearing can be used as a limit, so as to prevent changes in spectral level at a rate that may be detectable by human hearing. In this manner, response time system 310 can be used to prevent inadvertent masking, which can be created when changes in audio data exceed the speed at which they can be corrected by the human hearing mechanism, or when changes in spectral characteristics are tracked too slowly, resulting in loss masking of perceptual queues. Thus, while sample audio data may have a response time that exceeds the corrective mechanisms of human hearing, response time system 310 allows the effect of such components of the sample audio data to be minimized in the generation of the spectral characteristics for each band. Response time system 310 can also be used to detect the response of sample audio data. Response time system 310 allows response time to be set for each spectral band, a set of spectral bands, every spectral band, or other suitable combinations.

Threshold level system 312 allows a user to select a threshold level below which audio data within a spectral band will not be provided. In this manner, threshold level system 312 can be used to eliminate audio data that is not perceived by human hearing but which can generate masking of perceptual queues. Likewise, threshold level system 312 can be used to detect a threshold level in sample audio data. Threshold level system 312 allows threshold level to be set for each spectral band, a set of spectral bands, every spectral band, or other suitable combinations.

Target level system 314 is used to maintain an adaptive gain level selected by a user. In one exemplary embodiment, target level system 314 can be set to a zero gain setting during a training mode, during which time sample audio data is processed to determine the target gain settings for each of a plurality of spectral bands. These target gain levels can then be used by target level system 314 in a processing mode to set the adaptive gain levels for processing of target audio data, so as to impart the desired aesthetic qualities from the sample audio data to the target audio data.

RMS detector system 316 is used to determine the gain level of audio data for a spectral band, so as to allow the gain level to be corrected by an adaptive gain control. RMS detector system 316 thus allows the target gain level to be determined for a spectral band of sample audio data that has desired aesthetic qualities, such as in a training mode. The target gain level data is then provided to target level system 314, so as to allow target audio data to be processed in a processing mode.

In operation, system 300 allows spectral characteristics of sample audio data to be quantified, modified, and stored for use in processing audio data. System 300 can include artificial intelligence systems that generate spectral characteristics for controlling the level of audio data within predetermined bands, so as to control the spectral characteristics of an audio sample that provide preferred aesthetic qualities of the audio data. In this manner, system 300 allows target audio data to be processed to provide the target audio data with aesthetic qualities from sample audio data, by determining spectral characteristics of the sample audio data and by processing the target audio data to provide it with the spectral characteristics. System 300 also allows the spectral characteristics to be modified or entered by a user, such as to allow the user to determine the effect of the spectral characteristic on the target audio data.

FIG. 4 is a diagram of a system 400 for providing audio image management functionality in accordance with an exemplary embodiment of the present invention. System 400 includes image management system 108 and causal signal system 402, acausal signal system 404, causal shaping system 406, acausal shaping system 408, causal parameter system 410, and acausal parameter system 412, each of which can be implemented in hardware, software, or a suitable combination of hardware and software, and which can be one or more software systems operating on a general purpose processing platform.

Causal signal system 402 generates causal audio data from sample audio data. In one exemplary embodiment, causal signal system 402 can take left stereo channel data, right stereo channel data, as well as multiple additional channels such as those defined pursuant to MPEG-2 (including a subwoofer channel) and perform an addition operation on the data so as to generate causal signal data that is the sum of the selected channels of data. In this manner, causal signal system 402 duplicates the effect on hearing of a listener who is positioned at one point of an equilateral triangle, where the left and right stereophonic speakers are positioned at other two remaining points of the equilateral triangle and are oriented along a plane parallel to the plane intersecting both of the listener's ears, or at the equivalent location for systems that include multiple additional channels such as those defined pursuant to MPEG-2. The listener will perceive audio data from the left and right stereophonic speakers (or other combinations of speakers) at this point as being the sum of the signals. Thus, causal signal system 402 simulates the audio data signal perceived by the listener at that point.

Acausal signal system 404 generates acausal audio data. The acausal audio data includes the audio data from one stereophonic channel or other additional channels such as those defined pursuant to MPEG-2, subtracted from audio data from one of the other channels. In this manner, acausal signal system 404 generates the audio signal perceived by the listener from reflected sound. For example, in the system in which the user is sitting at one point of an equilateral triangle and the left and right stereophonic speakers are at the other points of the equilateral triangle, the room in which the listener and the stereophonic speakers are placed will also generate audio data, such as by reflecting the audio data generated by the left and right stereophonic speakers. The reflected audio data is perceived by the human ear of the listener as the difference between the audio data generated by the left and right stereophonic speakers. This reflected sound generates audio image data at other locations around the room. Likewise, in systems that include stereo left and right channels and multiple additional channels such as those defined pursuant to MPEG-2, the reflected sound represents differences between the various channels. Thus, the causal signal data generated by causal signal system 402 and the acausal signal data generated by acausal signal system 404 create a three dimensional audio image to the listener, which can create the appearance of sound coming from locations other than the stereophonic loud speakers.

Causal shaping system 406 receives the causal signal data from causal signal system 402 and performs a spectral characteristic analysis of the causal signal. In one exemplary embodiment, causal shaping system 406 determines the spectral characteristics for two or more spectral bands of the causal signal data, such as by interfacing with system 300, by performing independent functions similar to those performed by system 300, or in other suitable manners. Thus, causal shaping system 406 can include two or more artificial intelligence systems that determine the spectral characteristics of the causal signal data. In this manner, causal shaping system 406 can be used to generate audio image characteristics that include causal data characteristics for controlling and processing audio data. Likewise, a user can modify one or more of the causal characteristics, such as the transfer function, response time, threshold level, maximum gain, spectral band width, or other suitable characteristics, so as to determine the effect of such modifications on the aesthetic qualities of the processed audio data.

Acausal shaping system 408 receives the causal signal data from acausal signal system 404 and performs a spectral characteristic analysis of the acausal signal. In one exemplary embodiment, acausal shaping system 408 determines the spectral characteristics for two or more spectral bands of the acausal signal data, such as by interfacing with system 300, by performing independent functions similar to those performed by system 300, or in other suitable manners. Thus, acausal shaping system 408 can include two or more artificial intelligence systems that determine the spectral characteristics of the causal signal data. In this manner, acausal shaping system 408 can be used to generate audio image characteristics that include acausal data characteristics for controlling and processing audio data. Likewise, a user can modify one or more of the acausal characteristics, such as the transfer function, response time, threshold level, maximum gain, spectral band width, or other suitable characteristics, so as to determine the effect of such modifications on the aesthetic qualities of the processed audio data.

Causal parameter system 410 is used to track one or more causal parameters generated by causal shaping system 406, such as for use by an audio processing system 110. In one exemplary embodiment, causal parameter system 410 can include level data generated by processing a sample of data to determine causal characteristics, corresponding neural network characteristics for controlling the level data, and other suitable causal parameters. In this manner, causal parameter system 410 can store one or more sets of causal parameter data, such as to allow a user to compare different causal parameters to determine the effect on the aesthetic qualities of the audio data of the different sets of causal parameters.

Acausal parameter system 412 is used to track one or more acausal parameters generated by acausal shaping system 408, such as for use by an audio processing system 110. In one exemplary embodiment, acausal parameter system 412 can include level data generated by processing a sample of data to determine acausal characteristics, corresponding neural network characteristics for controlling the level data, and other suitable acausal parameters. In this manner, acausal parameter system 412 can store one or more sets of acausal parameter data, such as to allow a user to compare different acausal parameters to determine the effect on the aesthetic qualities of the audio data of the different sets of acausal parameters.

In operation, system 400 allows audio image characteristics to be determined, modified, and managed so as to allow audio data to be processed to match aesthetic characteristics associated with the audio image characteristics. In this manner, system 400 allows causal and acausal signal data to be generated, acausal and causal characteristics to be determined, and acausal and causal parameters to be stored for use in processing audio data. Likewise, system 400 allows a user to adjust the causal parameters and characteristics and to determine the effect on the aesthetic qualities of audio data.

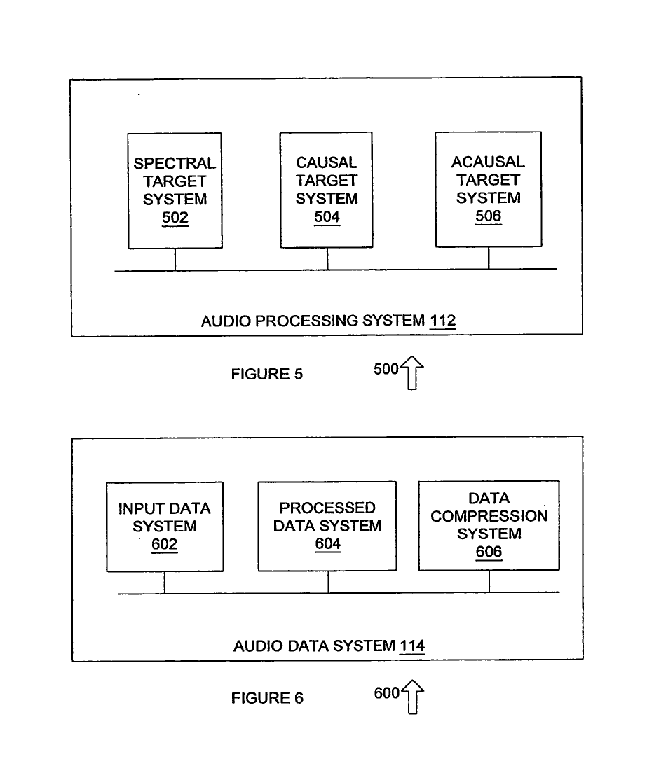

FIG. 5 is a diagram of a system 500 for processing audio data in accordance with an exemplary embodiment of the present invention. System 500 includes audio processing system 110 and spectral target system 502, causal target system 504 and acausal target system 506, each of which can be implemented in hardware, software, or a suitable combination of hardware and software, and which can be one or more software systems operating on a general purpose processing platform.

Spectral target system 502 receives audio data and spectral characteristics and processes the audio data so as to maintain spectral targets and other spectral characteristics. In one exemplary embodiment, spectral target system 502 can receive a number of settings of input, modifiers, conditionals, or other suitable characteristics for a neural network, including the definition of an open variable transfer function, and can also receive spectral characteristics such as an output, where the output is maintained as a target level in accordance with the other inputs, modifiers, conditionals, or other suitable characteristics. In this manner, spectral target system 502 maintains spectral targets of the audio data so as to provide the audio data with the aesthetic qualities of sample audio data. Likewise, spectral target system 502 can be used to maintain user selected spectral targets, such as when a user enters and modifies spectral targets so as to achieve aesthetic qualities are present in sample audio data. Spectral target system 502 can perform these functions on one or more sets of audio data, such as left and right stereophonic channel data or other suitable sets of audio data.

Causal target system 504 receives audio data and causal audio image characteristics and processes the audio data so as to maintain causal targets and other causal characteristics of the audio image data. In one exemplary embodiment, causal target system 504 can receive a number of settings of input, modifiers, conditionals, or other suitable characteristics for a neural network, including the definition of an open variable transfer function, and can also receive causal characteristics such as an output, where the output is maintained as a target level in accordance with the other inputs, modifiers, conditionals, or other suitable characteristics. In this manner, causal target system 504 maintains causal targets of the audio image characteristics so as to provide the audio image data with the aesthetic qualities of sample audio data. Likewise, causal target system 504 can be used to maintain user selected causal targets, such as when a user enters and modifies causal targets so as to achieve aesthetic qualities are present in sample audio data.

Acausal target system 506 receives audio data and acausal audio image characteristics and processes the audio data so as to maintain acausal targets and other acausal characteristics of the audio image data. In one exemplary embodiment, acausal target system 506 can receive a number of settings of input, modifiers, conditionals, or other suitable characteristics for a neural network, including the definition of an open variable transfer function, and can also receive acausal characteristics such as an output, where the output is maintained as a target level in accordance with the other inputs, modifiers, conditionals, or other suitable characteristics. In this manner, acausal target system 506 maintains acausal targets of the audio image characteristics so as to provide the audio image data with the aesthetic qualities of sample audio data. Likewise, acausal target system 506 can be used to maintain user selected acausal targets, such as when a user enters and modifies acausal targets so as to achieve aesthetic qualities are present in sample audio data.

In operation, system 500 allows audio data to be processed to set and maintain spectral targets for left and right channels of stereo data, multiple additional channels such as those defined pursuant to MPEG-2, causal targets, and acausal targets, so as to reproduce aesthetic characteristics of sample audio data in target audio data, to control the aesthetic characteristics of target audio data in accordance with user selections, or for other suitable purposes. In this manner, system 500 can be used to provide target audio data with aesthetic qualities and prevent masking of perceptual queues.

FIG. 6 is a diagram of a system 600 for managing audio data in accordance with an exemplary embodiment of the present invention. System 600 includes audio data system 112 and input data system 602, processed data system 604, and data compression system 606, each of which can be implemented in hardware, software, or a suitable combination of hardware and software, and which can be one or more software systems operating on a general purpose processing platform.

Input data system 602 receives audio data for processing. The audio data can be target audio data that is unprocessed or that has previously been processed but which lacks desired aesthetic qualities, sample audio data for use in generating spectral characteristic data and audio image characteristic data, or other suitable input data. Input data system 602 allows the user to readily identify and mark target audio data, target audio data that has been processed with one or more sets of spectral or audio image characteristic data, and other suitable input data.

Processed data system 604 allows the user to store processed audio data that is ready for compression. In one exemplary embodiment, processed data system 604 allows the user to identify versions of target audio data that have been processed using different sets of spectral characteristic data and audio image characteristic data, so as to allow the user to compare the aesthetic qualities of the processed target audio data. Likewise, processed data system 604 can allow the user to compare the processed audio data with the input audio data from input data system 602, so as to determine any changes in aesthetic qualities.

Data compression system 606 receives the processed audio data from processed data system 604 and performs data compression on the processed audio data. In one exemplary embodiment, data compression system 606 can compress the audio data in a manner that minimizes inadvertent masking, such as by determining whether the spectral and audio image characteristics of the audio data have been changed by the compression process.

In operation, system 600 manages audio input data, processed audio data, and compressed audio data so as to allow users to control the audio data processing and to produce audio data having aesthetic characteristics determined by the user.

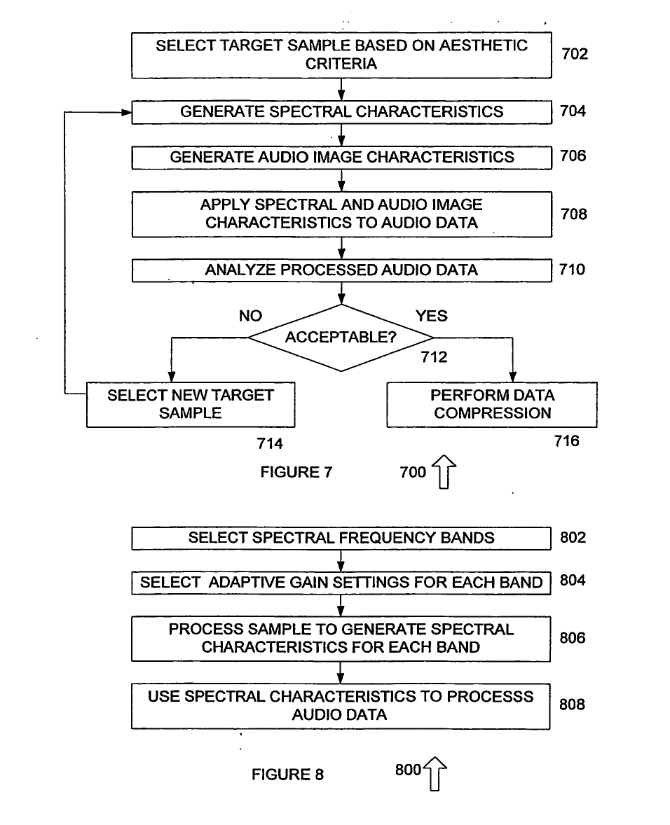

FIG. 7 is a flowchart of a method 700 for processing audio data in accordance with an exemplary embodiment of the present invention. Method 700 allows spectral characteristics and audio image characteristics to be quantified and controlled so as to control aesthetic characteristics of audio data.

Method 700 begins at 702 where a target sample is selected based on aesthetic criteria. In one exemplary embodiment, the user may listen to one or more sets of audio data, and can select target samples from the audio data based on requirements for sample size, aesthetic qualities or characteristics of interest to the user, or other suitable selection criteria. In this manner, the selection criteria can include subjective criteria, objective criteria, or a suitable combination of both. The method then proceeds to 704.

At 704, spectral characteristics are generated. In one exemplary embodiment, the spectral characteristics can include one or more spectral characteristics generated by determining the gain levels of two or more spectral bands and by storing additional spectral characteristics that are used to control the spectral characteristics of audio data, such as for processing of the audio data. The method then proceeds to 706.

At 706, audio image characteristic data is generated. In one exemplary embodiment, the audio image characteristic data can include causal characteristic data and acausal characteristic data that is used to produce aesthetic qualities in the audio data when it is played to a user or a listener. In this exemplary embodiment, audio image characteristics can be generated by adding left channel and right channel stereophonic audio data (or any suitable combination of multiple additional channels such as those defined pursuant to MPEG-2) to create causal data, determining the difference between the left channel and right channel stereophonic data (or any suitable combination of multiple additional channels such as those defined pursuant to MPEG-2) to create acausal data, and by determining spectral characteristics for the causal and acausal audio image data. In this matter, the audio image characteristics for a sample of audio data can be determined, such as when they will be used to process target audio data to provide it with aesthetic qualities of sample audio data. Likewise, the audio image characteristic data can be modified or provided by user so as to allow the user to process target audio data and determine the effect of the audio image characteristic data on the aesthetic qualities of the target audio data. The method proceeds to 708.

At 708, the spectral characteristics and audio image characteristics are applied to target audio data. The spectral characteristics and audio image characteristics can be applied to the target audio data by applying only the spectral characteristics to left channel and right channel stereophonic data (or other additional channels such as those defined pursuant to MPEG-2), by generating causal and acausal audio image data and then applying only the audio image characteristics to the causal and acausal data, applying a suitable combination of spectral characteristics and audio image characteristics, or in other suitable manners. The method then proceeds to 710.

At 710, the processed audio data is analyzed. In one exemplary embodiment, analysis can be formed subjectively, such as to determine whether the processed audio data has aesthetic characteristics desired by a user. Likewise, the audio data can be processed objectively, such as to determine whether the spectral characteristics of left channel and right channel stereophonic data are within predetermined levels, whether the audio image characteristics of causal and acausal data are within predetermined levels, or whether other conditions exist that would create unintended masking of audio data. The method then proceeds to 712.

At 712 it is determined whether the audio data is acceptable, such as whether it has acceptable aesthetic characteristics, objective characteristics, or other suitable characteristics. If the audio data is determined not to be acceptable at 712 the method proceeds to 714 where a new set of spectral and audio image data characteristics is selected. The new settings can also be selected from sample audio data, settings that were previously used can be modified, settings can be generated based on user preferences that are not obtained from target samples, or other suitable processes can be used. The method then returns to 704.

If it is determined at 712 that the processed audio data is acceptable the method proceeds to 716 where data compression is performed on the audio data. In one exemplary embodiment, the data compression can be performed or selected so as to minimize or prevent inadvertent masking from data compression, such as by using data compression techniques that have been determined to maintain the spectral characteristics and audio image characteristics of the audio data.

In operation, method 700 allows audio data to be processed to provide it with aesthetic characteristics in sample audio data, to allow a user to adjust or select spectral and audio image characteristics so as to produce aesthetic characteristics that are of interest to the user, or other suitable manners. Method 700 thus allows the processing of audio data to be focused on spectral and audio image components, to minimize the generation of masking and loss of perceptual queues.

FIG. 8 is a flow chart of a method 800 for generating spectral characteristics in accordance with an exemplary embodiment of the present invention. Method 800 allows sample audio data to be processed to determine the spectral characteristics of the sample audio data, and allows the spectral characteristics to be modified or generated by the user so as to control the aesthetic qualities of audio data and prevent masking of perceptual queues.

Method 800 begins at 802 where spectral frequency bands are selected. In one exemplary embodiment, the spectral frequency bands can be selected corresponding to a number of artificial intelligence processing systems, such as neural network systems that are used to learn response characteristics for spectral frequency band gain settings. In this exemplary embodiment, these spectral frequency bands can be set to a user selected frequency range, to concentrate frequency bands in areas in which human hearing is most sensitive. Likewise, where any suitable number of frequency bands and corresponding artificial intelligence processing systems can be used, the spectral frequency bands can be selected based on the characteristics of the audio data, aesthetic qualities, or other suitable characteristics. Frequency bandwidths can also be assigned based upon the relative audio data content of frequency bandwidths. In one exemplary embodiment, if an initial bandwidth assignment is used and no audio data is present in one or more bands for a section of audio data that lasts greater than a predetermined length of time, the frequency bands can be re-allocated to frequency ranges in which audio data is present, an alert can be generated for an operator to allow the operator to perform reallocation, bandwidth reallocation can be selected based on predetermined selections from a library of characteristic sets, or other suitable processes can be performed. The method then proceeds to 804.

At 804 adaptive gain settings are selected for each band. In one exemplary embodiment, the adaptive gain settings can include one or more inputs, modifiers, conditionals, or other suitable characteristics that are used to control the generation of spectral gain characteristics. For example, adaptive gain settings can include threshold levels, response times, maximum gain settings, transfer functions settings, target levels, or other suitable adaptive gain settings. Bands can be used for each variable that are accessible absolutely or cumulatively, and can further include inputs based on other spectral frequency bands, such as gain levels or settings. The method then proceeds to 806.

At 806 sample audio data is processed to generate spectral characteristic target gains for each spectral frequency band. For example, sample audio data can be processed using the spectral characteristics and parameters, such as to determine the target gain levels in each spectral band and how such target gain levels vary as a function of time, in relation to adaptive gain settings, in relation to spectral characteristics of other frequency bands, or other suitable data. The spectral characteristics can be used to maintain gain levels for each frequency band, such as by using an artificial intelligence system (e.g. a neural network) that uses the spectral characteristics to maintain the target output levels consistent with the behavior of the sample audio data. For example, response time for controlling changes in output level can be implemented in accordance with response time settings that are within the response times detectable by human hearing, so as to prevent inadvertent masking by allowing changes in spectral gain levels to occur faster than they can be heard by human hearing. Other suitable procedures can be used. The method then proceeds to 808.

At 808 the spectral characteristic targets are used to process audio data. In one exemplary embodiment, artificial intelligence systems are used to control audio data processors to maintain spectral band gain levels at target levels, consistent with the spectral characteristics generated at 806. Likewise, the spectral targets can be modified in accordance with user selected modifications, as a function of the frequency spectrum distribution of the audio data, using a library of characteristic data sets, or in other suitable manners.

In operation, method 800 allows spectral characteristics for sample audio data to be determined, and allows user to provide or modify the spectral characteristic data for use in processing target audio data. Method 800 allows the spectral characteristics to be used for processing audio data so as to maintain aesthetic qualities or provide aesthetic qualities, decrease masking of perceptual queues, and to provide other suitable functions.

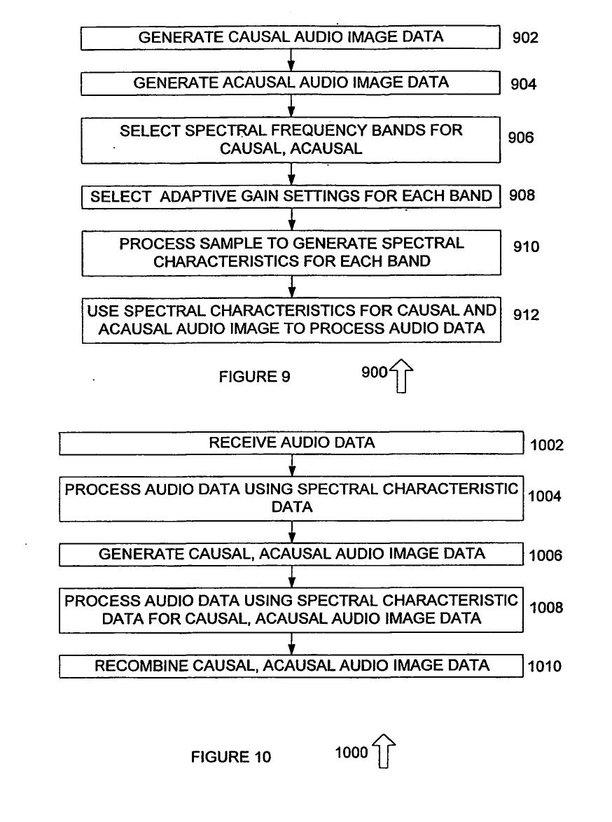

FIG. 9 is a flow chart of a method 900 for determining audio image characteristics in accordance with an exemplary embodiment of the present invention. Method 900 allows audio image characteristics to be set or determined from sample audio data so as to maintain aesthetic qualities and prevent masking of perceptual queues.

Method 900 begins at 902 where causal audio image data is generated. In one exemplary embodiment, the causal audio image data can be generated by adding stereophonic left channel data to stereophonic right channel data, such as to generate causal data that would be perceived by a listener at one point of a equilateral triangle, where the left and right stereophonic speaker channels are each at one of the other two points of the equilateral triangle and are oriented in a plane towards the listener. The method then proceeds to 904.

At 904, acausal audio image data is generated. For example, the acausal audio image data can be generated by subtracting the left channel data from the right channel data, the right channel data from the left channel data, or in other suitable manners that duplicate the effect of reflected sound on the listener's ear. The method then proceeds to 906.

At 906, spectral frequency bands are selected for the causal and acausal audio data. In one exemplary embodiment, spectral frequency bands selected for causal audio image data can be different from spectral frequency bands selected for acausal data, can be automatically detected based on optimal spectral frequency bands found in sample audio data having preferred aesthetic qualities, or can be otherwise selected. The method then proceeds to 908.

At 908, adaptive gain settings are selected for each band. For example, the adaptive gain settings can include threshold level, response time, maximum gain, transfer function, or other suitable settings that can be used to process the causal and acausal data so as to generate audio image characteristics that can be used to control audio data so as to produce desired aesthetic qualities. The method then proceeds to 910.

At 910, the sample is processed to generate spectral characteristic targets for each band. In one exemplary embodiment, sample audio data can be processed to detect these spectral characteristic targets for each band in the causal and acausal data, such as by using sample audio data that has predetermined aesthetic characteristics. Likewise, a user can provide settings or can modify setting obtained from using the sample audio data so as to provide other aesthetic characteristics. The method then proceeds to 912.

At 912 the spectral characteristic data is used to process causal and acausal audio data from target audio data. In one exemplary embodiment, the target audio data can include left channel and right channel stereophonic data, and the causal and acausal data can be processed after suitable addition or subtraction of the left and right channel data so as to maintain the spectral characteristics of the causal and acausal data. Likewise, the left and right channel data can first be processed to control spectral characteristics, and then the processed right and left channels can be used to generate causal and acausal data which can then be processed to further control the audio image characteristics. Other suitable processes can likewise be used.

In operation, method 900 allows audio image data characteristics to be generated from sample audio data, such as to reproduce the aesthetic qualities of the sample audio data. Method 900 also allows audio image data characteristics to be set or modified by user so as to provide aesthetic qualities not found in sample audio data, or for other suitable purposes. Method 900 can be used to minimize masking of perceptual queues so as to improve the aesthetic qualities of music by decreasing listener fatigue, masking or other undesirable characteristics of the music.

FIG. 10 is a flow chart of method 1000 for processing audio data using spectral characteristics and audio image characteristics in accordance with an exemplary embodiment of the present invention. In one exemplary embodiment, method 1000 can be used to process audio data prior to distribution. In another exemplary embodiment, method 1000 can be used to process audio data where the audio data is provided in an unprocessed format and the spectral and audio image characteristics are provided in an encoded or encrypted format so as to allow user access to target audio data but to charge an additional fee for allowing users to listen to the audio data with optimal spectral and audio image characteristics. Method 1000 can likewise be used for or in conjunction with other suitable processes.

Method 1000 begins at 1002 where the. audio data is received. The audio data can be received at a studio, an audio data processor, can be received by a listener, or other suitable audio data reception points can be established. The method then proceeds to 1004.

At 1004, the audio data is processed using spectral characteristic and audio image characteristic data. In one exemplary embodiment, the left and right stereophonic channels can be processed using artificial intelligence systems and spectral characteristics to maintain target gain levels, so as to reproduce aesthetic qualities of the audio data, prevent masking of perceptual queues, or for other suitable purposes. The method then proceeds to 1006.

At 1006, causal and acausal audio image data is generated, such as by adding and subtracting left and right stereophonic audio data channels in a suitable manner, or by other suitable processes. The method then proceeds to 1008.

At 1008, audio data is processed using spectral characteristic targets for causal and acausal audio image data. Processing of the audio data in this manner allows the spectral target levels to be maintained for both the causal and acausal audio image, such as to minimize changes in these characteristics that would not be perceived by human listeners but which would result in masking of perceptual queues. The method then proceeds to 1010.

At 1010 the causal and acausal audio image data is recombined to form stereophonic channel data for use by a listener. In one exemplary embodiment, the acausal audio image data can be added to the causal audio image data to form the left or right stereophonic channel data, and the acausal audio image data can be subtracted from the causal audio image data to generate the other remaining stereophonic channel data. Other suitable processes can also or alternatively be used.

In operation, method 1000 allows audio data to be processed to provide aesthetic characteristics to the audio data. These aesthetic characteristics can be provided by user, can be based on processed audio data from other sources, or other suitable characteristics can be used. In this manner, method 1000 allows audio data to be processed without significant user interaction. Likewise, method 1000 allows audio data to be provided in an unprocessed form, such as to a predetermined class of users for a reduced fee or no fee, and allows improved audio data to be provided to users for an additional fee, in response to user aesthetic selections or in other suitable manners. In this manner, production and processing of audio data can be simplified so as to provide desired aesthetic qualities without manual control of audio data generation characteristics.

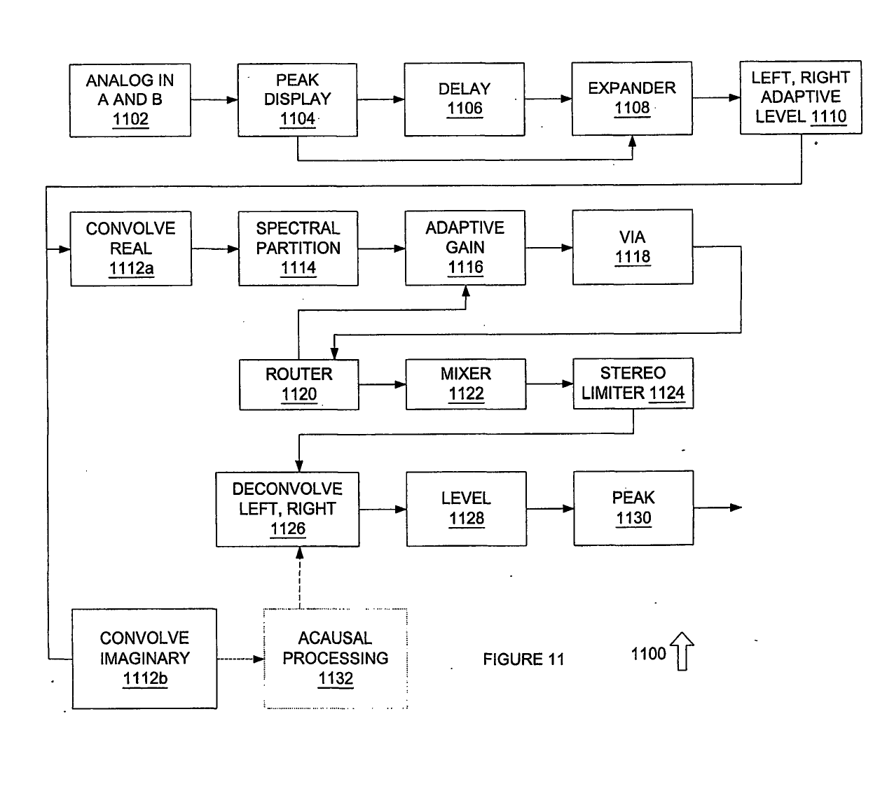

FIG. 11 is a flow diagram of a process 1100 for modifying audio data using spectral characteristics and audio image characteristics in accordance with an exemplary embodiment of the present invention. In one exemplary embodiment, flow diagram 1100 can be implemented as a series of user-selectable screen controls, where one or more control expands to reveal user-selectable controls, such as with the Peavey Mediamatrix software package available from Peavey Electronics Corporation of Meridian, Miss., or other suitable software packages.

Process 1100 begins at 1102, where two analog signals are received, such as from two or more microphones, a mixer board that outputs two stereophonic analog channels of data, or other suitable data sources. The peak of the signal is then displayed over peak display 1104, and a 4.99 millisecond delay is introduced by delay processor 1106. The signals are then expanded through expander with sidechain 1108 which also receives a sidechain signal from peak display 1104, and the optimum level is selected using left and right adaptive level 1110. The two channels of data are then processed to form the causal and acausal data using convolve real 1112a and convolve imaginary 1112b. The processing of the causal and acausal signals can then be performed in parallel.

At 1114, a spectral partition is used to separate the signal into a predetermined number of frequency bands. Each band is then processed using adaptive gain 1116, and a via 1118 and router 1120 are used to select between a training mode and an audio processing mode. In the training mode, the router 1120 is on and feeds a signal back to adaptive gain 1116. When a sampled section of audio data is selected having the aesthetic qualities desired by a listener, the router 1120 is turned off and the adaptive gain 1116 target settings are set for each spectral band so as to cause the adaptive gain 1116 for each spectral band to seek the levels set during the training process. The router 1120 is then turned back on, and the spectral gain target settings are used to maintain the spectral gain levels in the target audio data. A mixer 1122 is then used to combine the separate spectral bands, and a stereo limiter 1124 is used to post-process the causal data.

The causal and acausal data are then combined by deconvolve left right 1126, which also receives processed acausal data from an acausal processing sequence 1132 that matches the causal processing sequence. Level 1128 and peak 1130 are then used to post-process the left and right channel data.

In operation, process 1100 is used to perform processing of target audio data using settings derived from sample audio data. Process 1100 can be implemented using one or more pre-configured software controls.

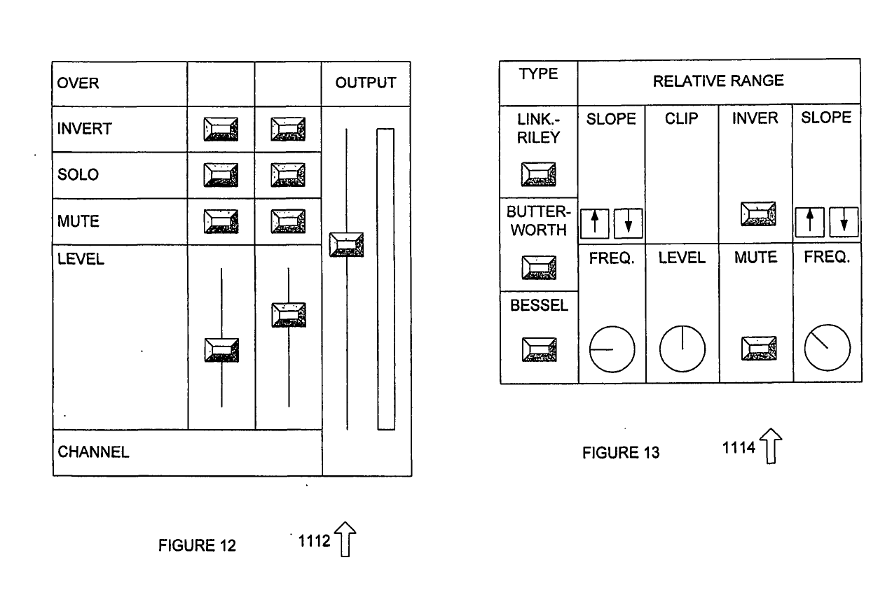

FIG. 12 is a diagram of a convolve control 1112 for generating causal or acausal audio data in accordance with an exemplary embodiment of the present invention. Convolve control 1112 includes overdrive indicators for each of two channels, selectable invert controls that allow the waveforms of either channel to be inverted, selectable solo controls, selectable mute controls, and adjustable level controls. An adjustable output control and peak indicator with markings in decibels (not shown) can also be provided.

FIG. 13 is a diagram of a spectral partition control 1114 for processing audio data in accordance with an exemplary embodiment of the present invention. Spectral partition control 1114 is an exemplary control for one of a predetermined number of spectral partitions. Selectable filter type controls, such as Linkwitz-Riley, Butterworth, and Bessel, are provided for each spectral partition, all spectral partitions, or other suitable combinations of spectral partitions. Each relative range setting can also have an adjustable low-end and high-end frequency range setting, a slope adjust control and display of present slope setting for the low-end and high-end frequency, a clip level control and clip display showing whether signal clipping is occurring, a selectable invert control, a selectable mute control, and other suitable settings.

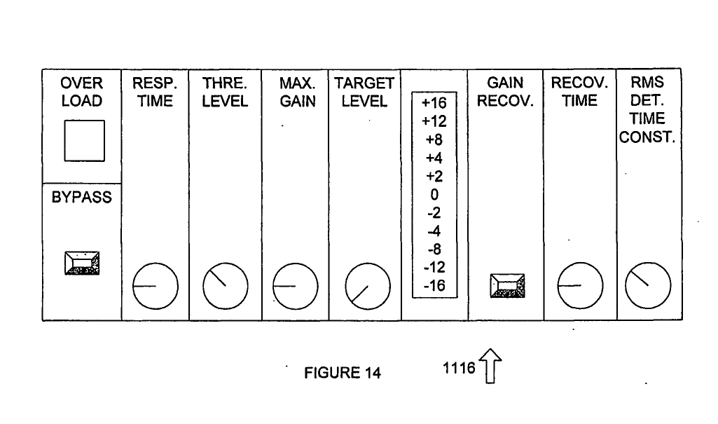

FIG. 14 is a diagram of an adaptive gain control 1116 for processing audio data in accordance with an exemplary embodiment of the present invention. Adaptive gain control 1116 includes an overload indicator, a selectable bypass control, an adjustable response time control and display, an adjustable threshold level control and display, an adjustable maximum gain control and display, a selectable gain recovery control, an adjustable recovery time control and display, and an adjustable RMS detector time constant and display. Adaptive gain control 1116 also includes an adjustable target level and display with markings ranging from a negative to a positive dB range (such as from −16 dB to +16 dB as shown). In this manner, sample audio data can be processed in a training mode wherein the RMS detector time constant and display is used to generate a current RMS gain level that is then used by adaptive gain control 1116 to control the gain to a 0.0 gain level. When router 1120 of FIG. 11 is turned off, then the gain level from the RMS detector for each spectral band is used as the target level setting, such as by increasing or decreasing the target level setting by the amount of gain shown by the RMS detector for the sample period. This setting can then be used in a second mode of operation when the router is turned back on to adaptively control the spectral band level of target audio data. In this manner, the adaptive gain control 1116 will maintain those target levels (which are the same settings as for the sample audio data) for target audio data, thereby imparting the aesthetic qualities from the sample audio data to the target audio data. It should be noted that in order for the RMS detector levels to be determined in this manner when the router 1120 is turned off, that the gain recovery setting must not be selected (gain recovery OFF).

Although exemplary embodiments of a system and method of the present invention have been described in detail herein, those skilled in the art will also recognize that various substitutions and modifications can be made to the systems and methods without departing from the scope and spirit of the appended claims.

What is claimed is:

1. A system for processing audio data comprising:
a spectral shaping system receiving sample audio data and generating spectral characteristic data for a plurality of spectral bands, wherein the spectral characteristic data includes spectral characteristic data for predetermined frequency bands for a combination of one or more left channel data, one or more right channel data, or one or more additional channel data such as those defined pursuant to MPEG-2, and a difference between the one or more left channel data, the one or more right channel data, or the one or more additional channel data; and
an audio processing system receiving the spectral characteristic data and processing the audio data so as to provide the spectral characteristic data for the spectral bands of the audio data.

2. The system of claim 1 wherein the spectral shaping system further comprises a spectral parameter system generating target level data for each of the predetermined frequency bands for the combination of the one or more left channel data, the one or more right channel data, or any of the one or more additional channel data, and the difference between the one or more left channel data, the one or more right channel data, or the one or more additional channel data.

3. The system of claim 2 wherein the spectral shaping system comprises a neural network and the spectral characteristic data includes neural network parameters generated after processing the sample audio data to allow the audio data to be processed so as to provide the spectral characteristic data for the spectral bands of the audio data.

4. The system of claim 1 further comprising an image management system receiving two or more channels of audio data and generating causal audio data that includes the combination of the one or more left channel data, the one or more right channel data, or the one or more additional channel data, and acausal audio data that includes the difference between the one or more left channel data, the one or more right channel data, or the one or more additional channel data, wherein the sample audio data includes the two or more channels of audio data.

5. The system of claim 1 further comprising an image management system receiving two or more channels of audio data and generating audio image characteristic data for controlling one or more three dimensional characteristics of the two or more channels of audio data.

6. The system of claim 5 wherein the image management system further comprises a causal parameter system and an acausal parameter system generating causal characteristic data and acausal characteristic data for controlling one or more three dimensional characteristics of the two or more channels of audio data.

7. The system of claim 6 wherein the causal parameter system and the acausal parameter system each comprise a neural network and the causal and acausal characteristic data includes neural network characteristics generated after processing the sample audio data for controlling one or more three dimensional characteristics of the two or more channels of audio data.

8. The system of claim 1 wherein the audio processing system further comprises a spectral target system receiving spectral characteristic data associated with target level data and processing the audio data to maintain the target level data as a function of the spectral characteristic data.

9. The system of claim 8 wherein the spectral target system includes a neural network and the spectral characteristic data includes neural network characteristics used for processing the audio data.

10. The system of claim 1 wherein the audio processing system further comprises:
a causal target system receiving causal characteristic data associated with the combination of the one or more left channel data, the one or more right channel data, or the one or more additional channel data for a causal target level and processing the audio data to maintain the causal target level as a function of the causal characteristic data; and
an acausal target system receiving acausal characteristic data associated with the difference between the one or more left channel data, the one or more right channel data, or the one or more additional channel data for an acausal target level and processing the audio data to maintain the acausal target level as a function of the acausal characteristic data.

11. The system of claim 8 wherein the causal target system and the acausal target system each include a neural network and the causal and acausal characteristic data each include neural network characteristics used for processing the audio data.

12. A method for processing audio data comprising:
selecting audio characteristic data based on audio sample data having predetermined characteristics;
generating causal spectral characteristic data for predetermined frequency bands of one or more left channel audio sample data combined with predetermined frequency bands of one or more right channel audio sample data, or or more additional channel audio sample data such as those defined pursuant to MPEG-2;
generating acausal spectral characteristic data for a difference between predetermined frequency bands of the one or more right channel audio sample data, the one or more left channel audio sample data, or the one or more additional channel audio sample data;
processing a combination of one or more left channel audio data, one or more right channel audio data, or one or more additional channel audio data such as those defined pursuant to MPEG-2 with the causal channel spectral characteristic data; and
processing a difference between the one or more left channel audio data, the one or more right channel audio data, or the one or more additional channel audio data with the acausal channel spectral characteristic data.

13. The method of claim 12 wherein selecting the audio characteristic data based on the audio sample data comprises selecting the audio characteristic data based on predetermined characteristics for the one or more left channel audio sample data, the one or more right channel audio sample data, or the one or more additional channel audio sample data.

14. The method of claim 12 further comprising:
generating one or more left channel audio data from the processed combination of the one or more left channel audio data, the one or more right channel audio data, or the one or more additional channel audio data and the processed difference between the one or more left channel audio data, the one or more right channel audio data, or the one or more additional channel audio data; and
generating left channel audio from the processed combination of the one or more left channel audio data, the one or more right channel audio data, or the one or more additional channel audio data and the processed difference between the one or more left channel audio data, the one or more right channel audio data, or the one or more additional channel audio data.

15. The method of claim 14 wherein generating the left channel audio from the processed combination of the one or more left channel audio data, the one or more right channel audio data, or the one or more additional channel audio data and the processed difference between the one or more left channel audio data, the one or more right channel audio data, or the one or more additional channel audio data comprises adding the processed combination of the one or more left channel audio data, the one or more right channel audio data, or the one or more additional channel audio data and the processed difference between the one or more left channel audio data, the one or more right channel audio data, or the one or more additional channel audio data.

16. The method of claim 12 wherein generating the right channel audio from the processed combination of the one or more left channel audio data, the one or more right channel audio data, or the one or more additional channel audio data and the processed difference between the one or more left channel audio data, the one or more right channel audio data, or the one or more additional channel audio data comprises subtracting the processed combination of the one or more left channel audio data, the one or more right channel audio data, or the one or more additional channel audio data from the processed difference between the one or more left channel audio data, the one or more right channel audio data, or the one or more additional channel audio data.

17. The method of claim 12 wherein generating the causal spectral characteristic data for the predetermined frequency bands of the one or more left channel audio sample data combined with the predetermined frequency bands of the one or more right channel audio sample data or the one or more additional channel audio data further comprises selecting the predetermined frequency bands for the causal spectral characteristic data so as to concentrate the predetermined frequency bands in areas in which human hearing is most sensitive to the causal spectral characteristic data.

18. The method of claim 12 wherein generating the acausal spectral characteristic data for the difference between the predetermined frequency bands of the one or more of the right channel audio sample data, the one or more of the left channel audio sample data, or the one or more additional channel audio data further comprises selecting the predetermined frequency bands for the acausal spectral characteristic data so as to concentrate the predetermined frequency bands in areas in which human hearing is most sensitive to the acausal spectral characteristic data.

19. The method of claim 12 wherein the predetermined frequency bands are selected from a library of characteristic sets.

20. The method of claim 12 wherein processing the combination of the one or more left channel audio data, the one or more right channel audio data, or the one or more additional channel audio data with the causal channel spectral characteristic data and processing the difference between the one or more left channel audio data, the one or more right channel audio data, or the one or more additional channel audio data with the acausal channel spectral characteristic data creates audio image data having a three-dimensional characteristic that matches audio image data of the audio sample data.
